(19) United States
(12) Patent Application Publication
(10) Pub. No.: US 2013/0176503 A1
(43) Pub. Date: Jul. 11, 2013

(54) TELEVISION RECEIVER AND ELECTRONIC APPARATUS

(71) Applicant: Koji ARIGA, Ome-shi (JP)

(72) Inventor: Koji ARIGA, Ome-shi (JP)

(73) Assignee: KABUSHIKI KAISHA TOSHIBA, Tokyo (JP)

(21) Appl. No.: 13/614,855

(22) Filed: Sep. 13, 2012

(30) Foreign Application Priority Data
Jan. 6, 2012 (JP) 2012-001471

(51) Int. Cl. H04N 5/50; H05K 7/00

(52) U.S. Cl. 348/731; 361/679.01; 348/E05.097

(57) ABSTRACT

According to one embodiment, an electronic apparatus includes an apparatus, a first portion and a second portion. The first portion is attached to a surface of the apparatus. The second portion includes a first supporting portion rotatably connected to the first portion and a second supporting portion arranged alongside the first supporting portion through a slit, the second supporting portion rotatably connected to the first supporting portion at a position shifted from the slit. The electronic apparatus is configured to transform between a first form where the second portion covers the apparatus and the second form where the second supporting portion supports the first portion to hold the apparatus in a tilted state by the rotation of the first and second supporting portions.

### CROSS-REFERENCE TO RELATED APPLICATIONS

This application is based upon and claims the benefit of priority from prior Japanese Patent Application No. 2012-001471, filed Jan. 6, 2012, the entire contents of which are incorporated herein by reference.

### FIELD

Embodiments described herein relate generally to a television receiver and electronic apparatus.

### BACKGROUND

A television receiver or any other electronic apparatus comprising a display unit configured to display an image would further comprise a cover configured to protect the display unit for safe carrying, for example. The cover would be used as a stand supporting the television receiver and the like.

In a case where the cover is configured to be used as a stand, the strength of a part of the cover covering the display unit of the television receiver may be decreased. Thus, there is a technical need to improve such a cover used as a stand.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view showing a TV according to an embodiment;

FIG. 2 is an exemplary side view showing the TV according to an embodiment;

FIG. 3 is an exemplary cross-sectional view showing the TV taken along line F3-F3 in FIG. 2;

FIG. 4 is an exemplary perspective view showing the TV disassembled according to an embodiment;

FIG. 5 is an exemplary plan view showing the TV viewed from the opposite side of FIG. 4;

FIG. 6 is an exemplary cross-sectional view of a cover taken along line F6-F6 in FIG. 5;

FIG. 7 is an exemplary side view showing a first supporting portion and a second supporting portion folded according to an embodiment;

FIG. 8 is an exemplary perspective view of the TV in a second form according to an embodiment;

FIG. 9 is an exemplary side view showing the TV whose cover is unfolded according to an embodiment;

FIG. 10 is an exemplary side view of the TV transformed into the second form according to an embodiment;

FIG. 11 is an exemplary perspective view of the TV in a third form according to an embodiment; and

FIG. 12 is an exemplary side view of the TV transformed into the third form according to an embodiment.

### DETAILED DESCRIPTION

Various embodiments will be described hereinafter with reference to the accompanying drawings.

In general, according to one embodiment, an electronic apparatus includes an apparatus, a first portion and a second portion. The apparatus includes a first surface and a second surface in an opposite side of the first surface. The first portion is attached to the second surface of the apparatus. The second portion includes a first supporting portion rotatably connected to the first portion and a second supporting portion arranged alongside the first supporting portion through a slit, the second supporting portion rotatably connected to the first supporting portion at a position shifted from the slit. The electronic apparatus is configured to transform between a first form where the second portion covers the first surface and the second form where the second supporting portion supports the first portion to hold the apparatus in a tilted state by the rotation of the first and second supporting portions.

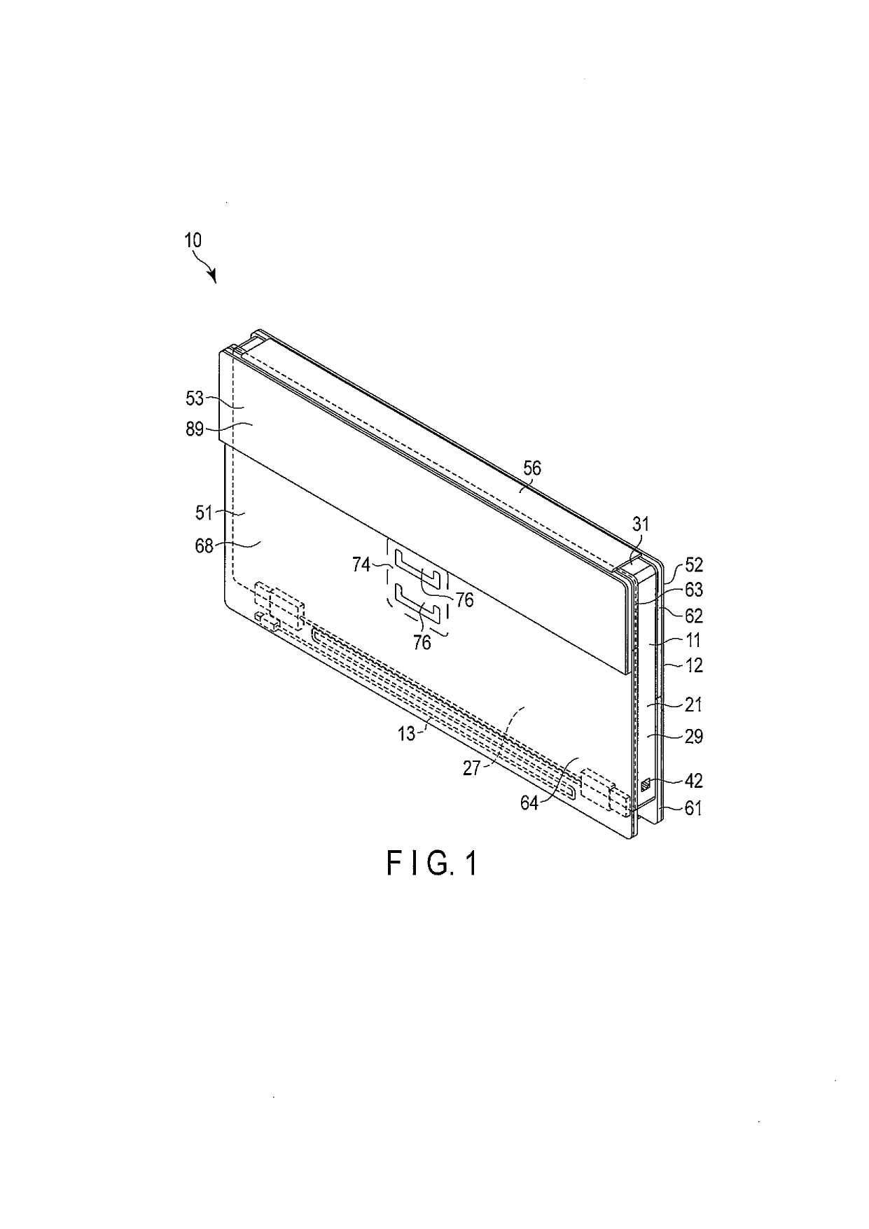

Hereinafter, an embodiment is described with reference to FIGS. 1 to 12. A name of each element below is only an example in the embodiment and is not limited to the name described below. Some elements are named in several ways but it does not mean that other single-named elements are only referred to by that name.

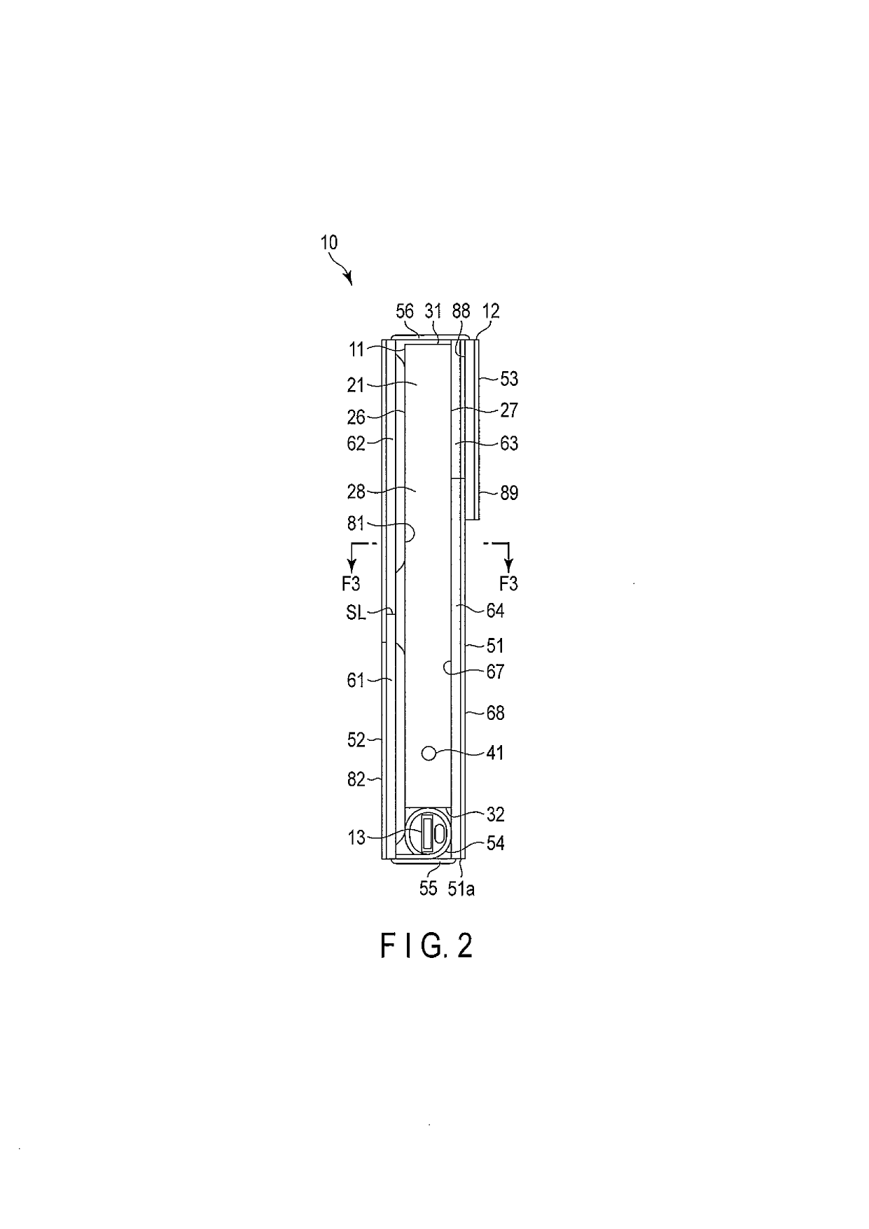

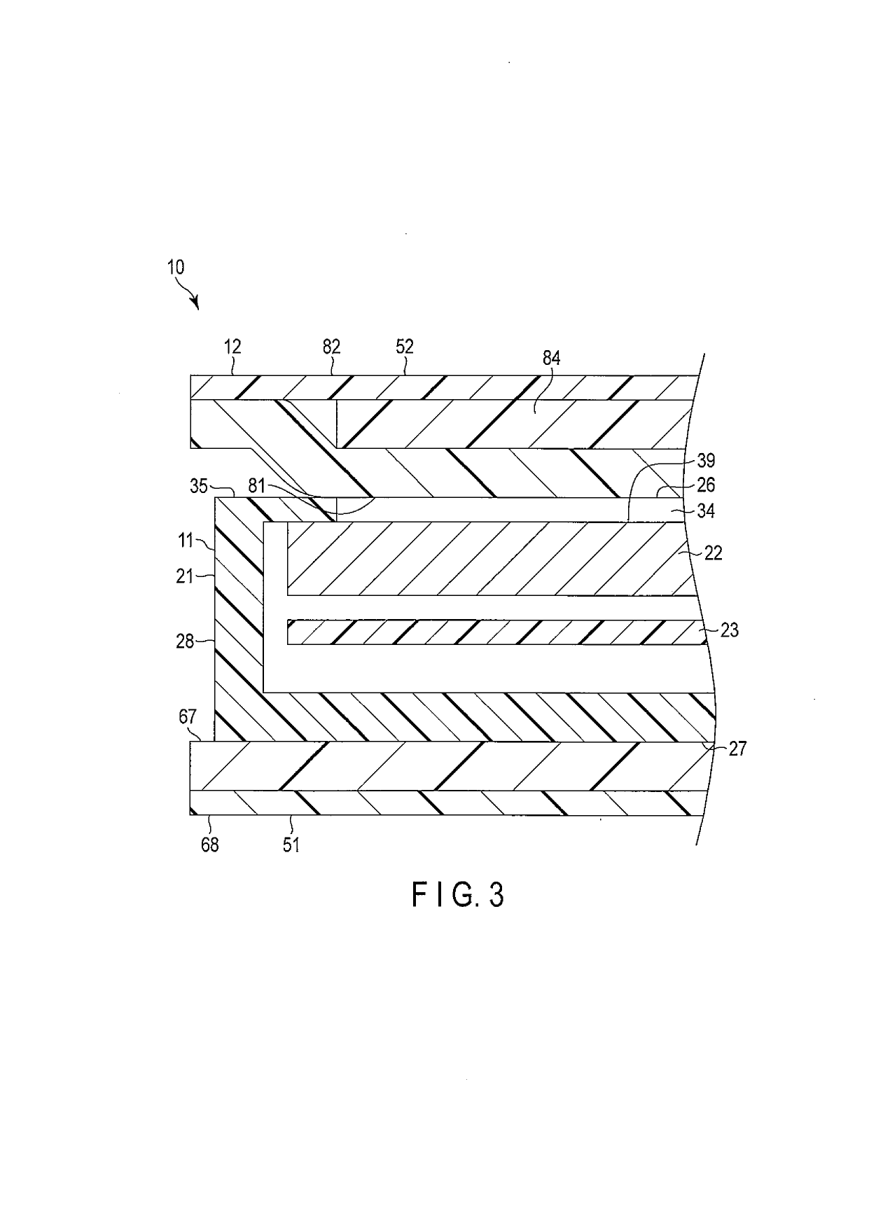

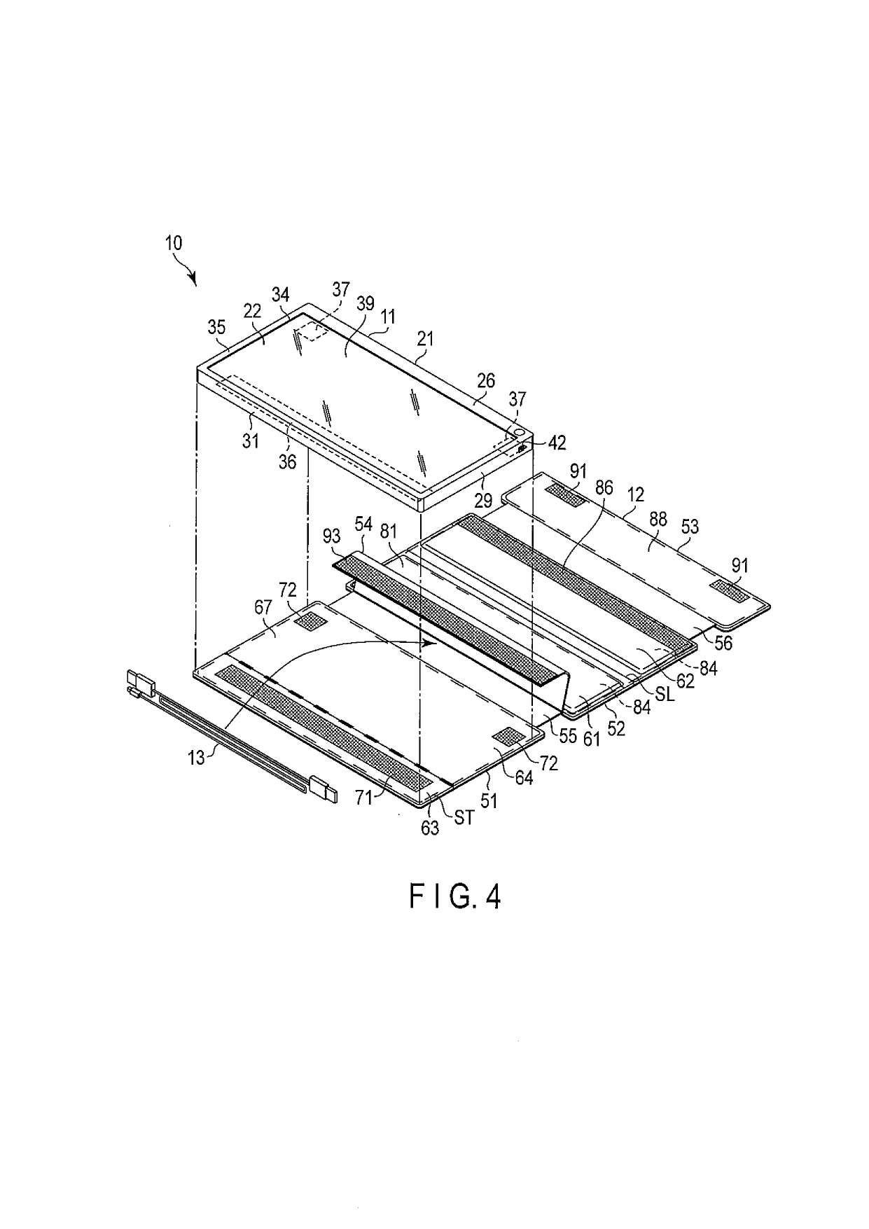

FIG. 1 is a perspective view of a television receiver (hereinafter referred to as TV) 10. FIG. 2 is a side view of the TV 10. FIG. 3 is a cross-sectional view of the TV 10 taken along line F3-F3 in FIG. 2. FIG. 4 is a perspective view of the TV 10 disassembled.

As shown in FIG. 1, the TV 10 comprises a receiver 11 (apparatus, display apparatus, main body, unit, part, display unit, and display), a cover 12 (case, outer part, covering part, protective part and part), and a cable 13. The receiver is an example of an apparatus.

The TV 10 is a portable television receiver which receives a radio wave by, for example, a built-in antenna. The TV 10 may receive a radio wave via, for example, the cable 13 or external connection apparatus.

As shown in FIG. 3, the receiver 11 comprises a housing 21 and a display module 22 (display unit, panel and part) and a circuit board 23 (substrate, part and electronic portion). The circuit board 23 is an example of a tuner.

The casing 21 is formed as a rectangular box. The casing 21 comprises a first surface 26 (surface, front surface), a second surface 27 (back, rear surface), a pair of side surfaces 28, 29 and a pair of end surfaces 31, 32 (upper surface and lower surface). The side surface 29 is shown in, for example, FIG. 1. The second surface 27 is opposite to the first surface 26. The end surfaces 31 and 32 are shown in, for example, FIG. 2. The side surfaces 28 and 29 cross the end surfaces 31 and 32, respectively. A rectangular opening 34 is provided on the first surface 26. The first surface 26 forms a frame portion 35 surrounding the opening 34.

As shown by a broken line in FIG. 4, a plurality of hook and loop fasteners 36 and 37 (fixing portions, attachment portions) are attached to the second surface 27 of the casing 21 by, for example, a double-sided tape. The hook and loop fastener 36 is an example of an attachment. The hook and loop fastener 36 is positioned nearby the end surface 31 of the casing 21. The two hook and loop fasteners 37 are positioned nearby the end surface 32 of the casing 21. Each of the hook and loop fasteners 37 is formed smaller than the hook and loop fastener 36.

A display module 22 is, for example, a liquid crystal display; however, it is not limited to the liquid crystal display and may be other image display modules such as plasma display and organic electroluminescent display, etc. The display module 22 comprises a display portion 39 (display, image display portion) configured to display an image. Here, in the present application, the term “image” includes a still picture and a moving picture. The display portion 39 is exposed from the opening 34 of the casing 21. In other words, the receiver 11 comprises the display portion 39 provided on the first surface 26. The display portion 39 is covered by, for example, an acrylic transparent panel.

As shown in FIG. 3, the circuit board 23 is contained in the casing 21. The circuit board 23 is, for example, a rigid printed circuit board. Various electronic components such as an image processing circuit, connector, tuner and antenna mentioned above are mounted on the circuit board 23. The circuit board 23 displays an image on the display portion 39 of the display module 22 based on radio waves received by the antenna and tuned by the tuner.

As shown in FIG. 2, a power supply socket 41 is provided in the side surface 28 of the casing 21. The power supply socket 41 is provided near to the end surface 32 of the casing 21. For example, a connector of an AC adaptor is inserted into the power supply socket 41.

As shown in FIG. 1, a USB socket 42 is provided in the side surface 29 of the casing 21. The USB socket 42 is provided near to the end surface 32 of the casing 21. A connector of a USB cable is inserted into the USB socket 42.

As shown in FIG. 4, the cable 13 is a so-called Y-shaped USB cable comprising three connectors. One connector of the cable 13 is inserted into the USB socket 42. The other two connectors of the cable 13 are connected with an external device such as a recording device and the like. The receiver 11 performs data transmission and power charge, etc. through the cable 13.

The cover 12 is made of, for example, synthetic leather and felt, etc. The cover 12 covers the receiver 11 for protection. As shown in FIG. 4, the cover 12 comprises a first portion 51 (part, region, range) and a second portion 52 (part, region, range), a fixing portion 53, a holding portion 54 (part, region, range), a first connecting portion 55 and a second connecting portion 56. Here, the felt is not slippery in comparison with the synthetic leather.

The first portion 51 and the second portion 52 are foldable in two, respectively. The second portion 52 comprises a first supporting portion 61 (part, region, range) and a second supporting portion 62 (part, region, range) provided on each folded portion of the second portion 52 centering a folding therebetween. The first supporting portion 61 is an example of a connection portion. The second supporting portion 62 is an example of a supporting portion. The first portion 51 comprises a third supporting portion 63 (part, region, range) and a fourth supporting portion 64 (part, region, range) provided on each folded portion of the first portion 51 centering a folding therebetween.

The first portion 51 is formed in a rectangular shape larger than the receiver 11. Thus, as shown in FIG. 2, the end surface 32 of the receiver 11 is distant from the end portion 51a of the first portion 51.

The first portion 51 comprises an inner surface 67 (surface, portion, region) and an outer surface 68 (surface, portion, region). The inner surface 67 is formed of, for example, felt. The outer surface 68 is positioned opposite to the inner surface 67 and formed of, for example, synthetic leather. As shown in FIG. 4, stitches ST are formed in a peripheral region of the inner surface 67. The stitches ST are formed in the second portion 52, the fixing portion 53 and the other portions.

A plurality of hook and loop fasteners 71 and 72 (fixing portion, attachment portion) are fixed to the inner surface 67 by, for example, stitching. The hook and loop fastener 71 is positioned at the third supporting portion 63 and corresponds to the hook and loop fastener 36 of the receiver 11. The two hook and loop fasteners 72 are positioned at the fourth supporting portion 64 and correspond to two hook and loop fasteners 37 of the receiver 11, respectively. Each of the hook and loop fasteners 72 is formed smaller than the hook and loop fastener 71.

The second surface 27 of the receiver 11 is detachably attached to the third supporting portion 63 of the first portion 51 according to the hook and loop fastener 36 attached to the hook and loop fastener 71. Thereby, the second surface 27 of the receiver 11 is attached to the first portion 51. Furthermore, the second surface 27 of the receiver 11 is detachably attached to the fourth supporting portion 64 of the first portion 51 according to the hook and loop fastener 37 attached to the hook and loop fastener 72. The adhesive force of the second surface 27 to the third supporting portion 63 is stronger than the adhesive force of the second surface 27 to the fourth supporting portion 64.

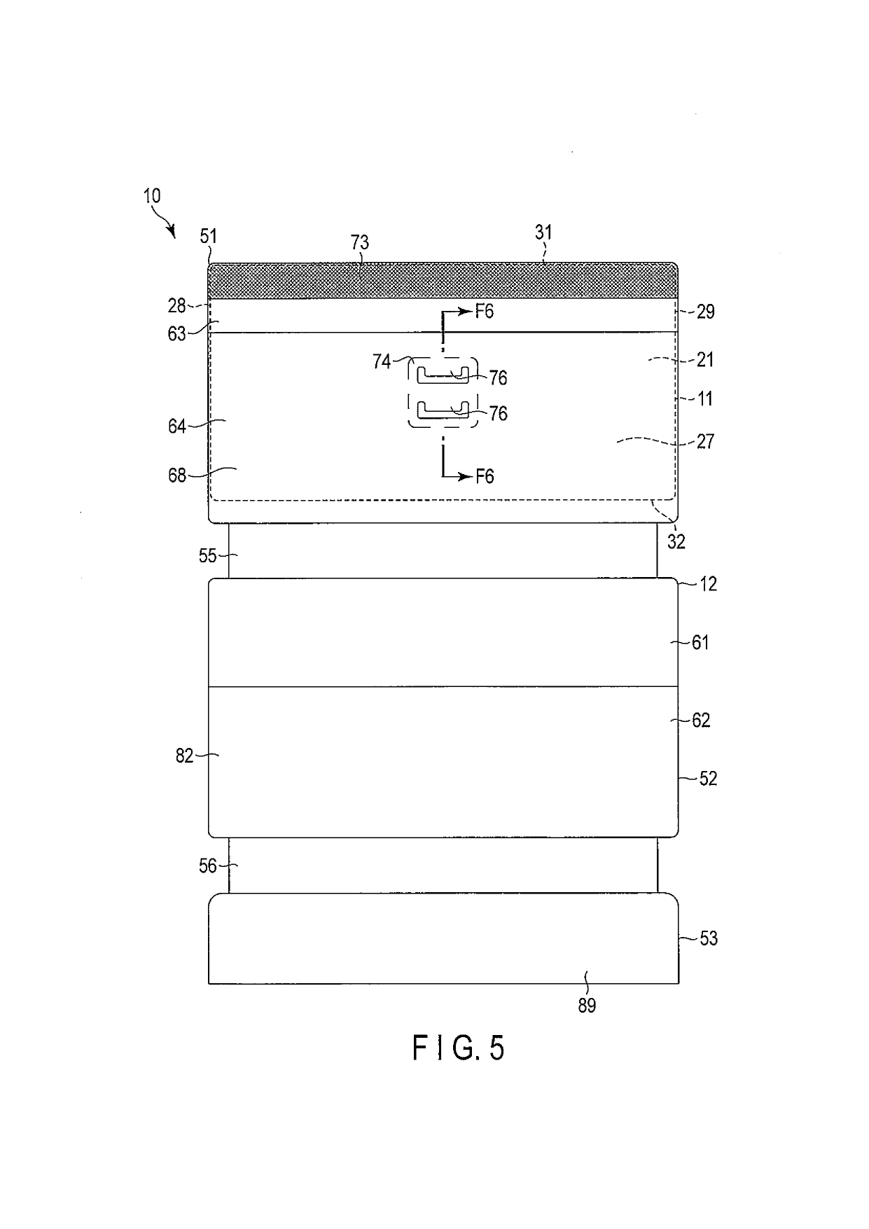

FIG. 5 shows a plan view of the TV 10 viewed from the opposite side of FIG. 4. As shown in FIG. 5, a hook and loop fastener 73 (fixing portion, attachment portion) is fixed to the outer surface 68 by, for example, stitching. The hook and loop fastener 73 is positioned at the third supporting portion 63. Instead of the hook and loop fastener 73, felt may be provided. The felt is attachable to a hook fastener comprising a plurality of hook-shaped projections.

The third supporting portion 63 and fourth supporting portion 64 of the first portion 51 are configured to be folded in two. In other words, the fourth supporting portion 64 is connected with the third supporting portion 63 rotatably with respect to the third supporting portion 63. The third supporting portion 63 is smaller than the fourth supporting portion 64.

An adjuster 74 is provided with the outer surface 68 of the first portion 51. The adjuster 74 is positioned at the fourth supporting portion 64. The adjuster 74 may be positioned at the third supporting portion 63.

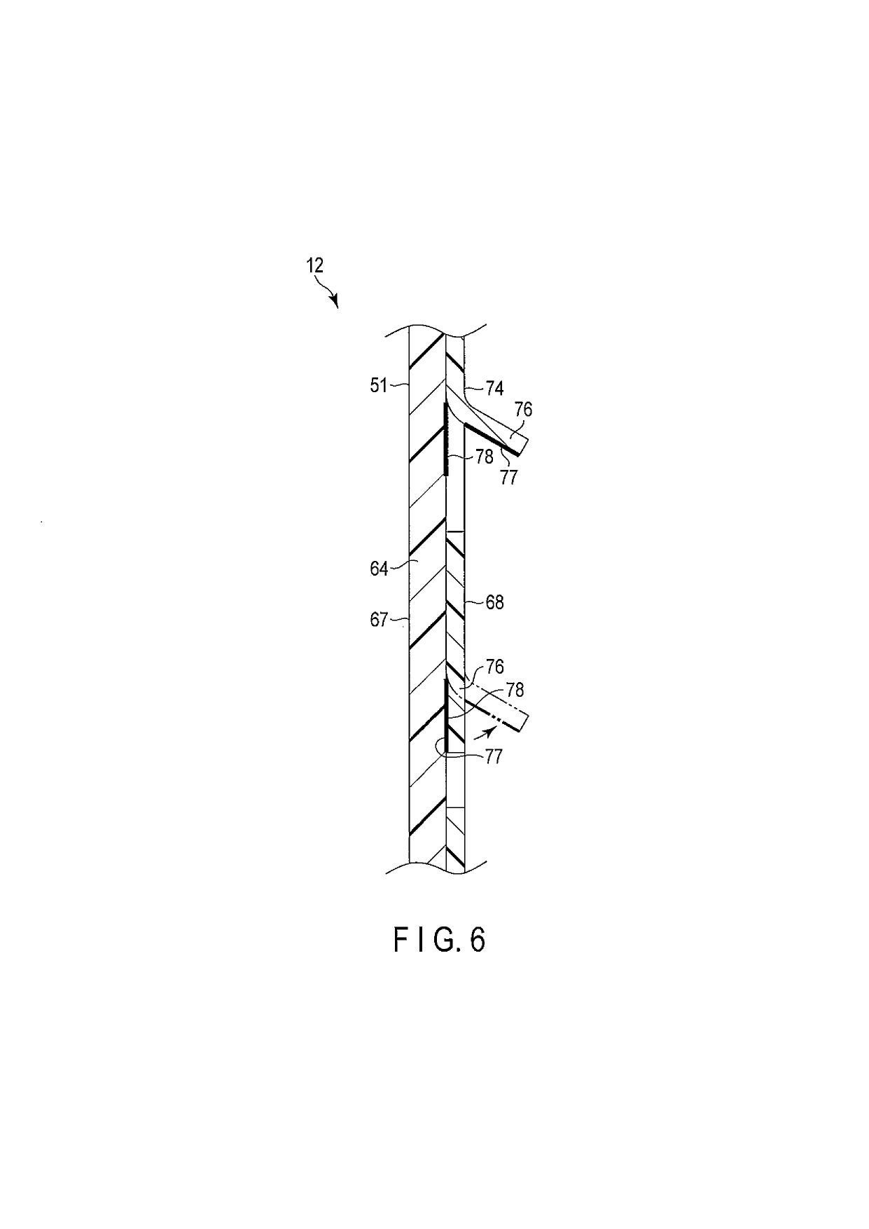

FIG. 6 is a cross-sectional view of the cover 12 taken along line F6-F6 in FIG. 5. As shown in FIG. 6, the adjuster 74 comprises two tabs 76. The tabs are arranged alongside.

As shown in FIG. 6 with a bold line, the tabs 76 comprises hook and loop fasteners 77 (fixing portion, attachment), respectively. The hook and loop fastener 77 of tabs 76 is attached to hook and loop fasteners 78 (fixing portion, attachment) provided on the outer surface 68 of the first portion 51. The tabs 76 are peeled off from the outer surface 68 of the first portion 51 in an open side fashion.

As shown in FIG. 4, the second portion 52 is formed in a rectangular shape which is larger than the receiver 11. The first portion 51 and the second portion 52 are formed to be substantially the same size. As shown in FIG. 3, the second portion 52 comprises a first surface 81 (surface, portion, region) and a second surface 82 (surface, portion, region). The first surface 81 of the second portion 52 is formed of felt and faces the receiver 11 as shown in FIG. 3. The second surface 82 of the second portion 52 is opposite to the first surface 81 and is formed of, for example, synthetic leather. Thus, the first surface 81 is not slippery in comparison with the second surface 82.

The second portion 52 is formed by stitching, for example, the felt forming the first surface 81 and the synthetic leather forming the second surface 82. A plurality of rigid members 84 are inserted between the felt and the synthetic leather. The rigid members 84 are a plate-like member formed of, for example, synthetic fiber. A part of the rigid members 84 may overlap with the frame portion 35 of the receiver 11.

As shown in FIG. 4, the rigid members 84 are provide with the first supporting portion 61 and the second supporting portion 62, respectively. Thus, the first and second supporting portions 61 and 62 are more rigid than the first portion 51.

The first supporting portion 61 is connected with the fourth supporting portion 64 of the first portion 51 through a first connecting portion 55. The first connecting portion 55 is formed of, for example, synthetic leather and is thus flexible. Thereby, the first supporting portion 61 is rotatable with respect to the fourth supporting portion 64 of the first portion 51. Here, the width of the first connecting portion 55 is wider than the thickness of the receiver 11. The connecting portion 55 may be formed of, for example, elastic rubber to set the width of the first connecting portion 55 narrower than the thickness of the receiver 11. The first connecting portion 55 extends from the end portion 51a of the first portion 51.

The first supporting portion 61 is smaller than the second supporting portion 62. The first supporting portion 61 and second supporting portion 62 of the second portion 52 are arranged alongside through a slit SL (opening, hole, aperture, concaved portion, part, region). Specifically, each part formed of felt and the rigid members 84 in the first and second supporting portions 61 and 62 of the second portion 52 is separated from each other. However, each part formed of synthetic leather in the first and second supporting portions 61 and 62 is successive with each other. Thus, the first supporting portion 61 and second supporting portion 62 are connected to each other.

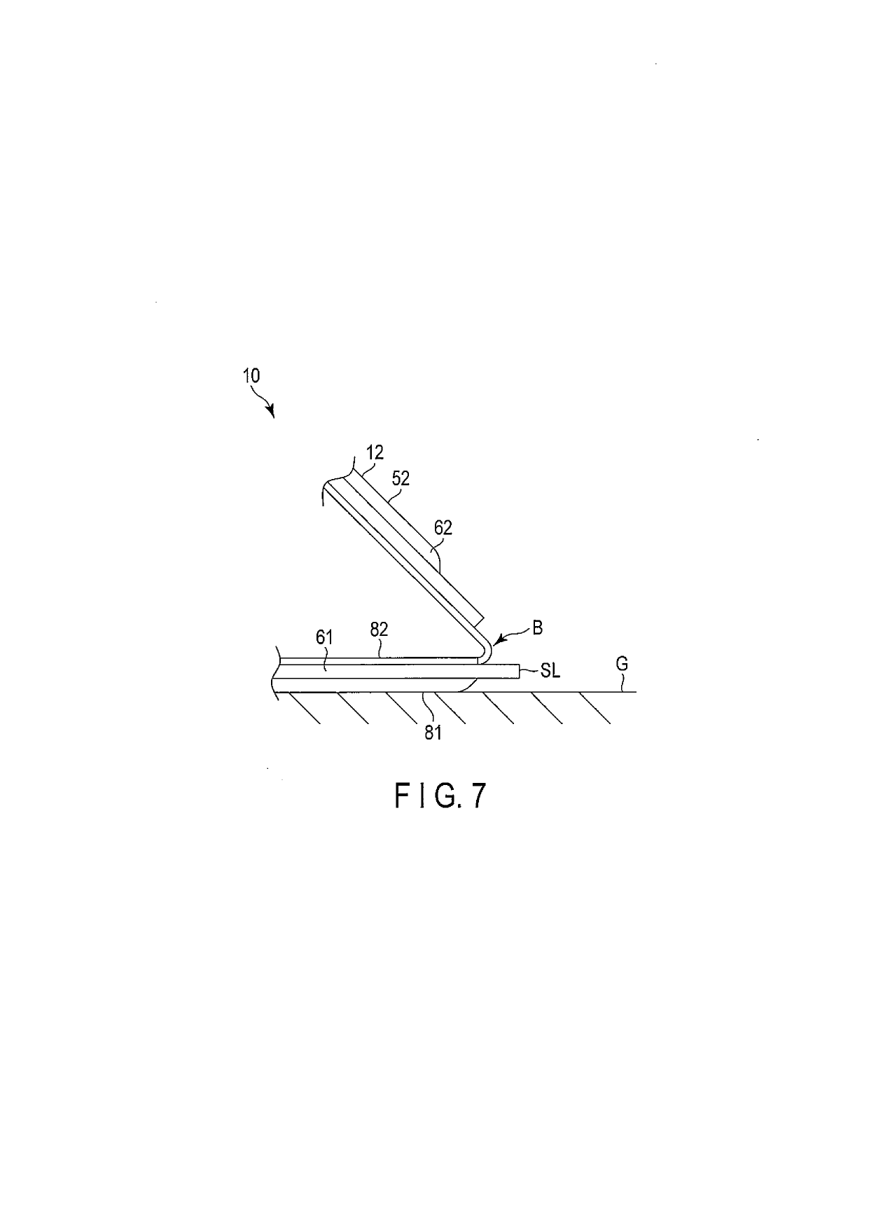

FIG. 7 shows a side view of the first supporting portion 61 and second supporting portion 62 folded. As shown in FIG. 7, the first supporting portion 61 and second supporting portion 62 are configured to be folded in two. In other words, the second supporting portion 62 is connected to the first supporting portion 61 rotatably with respect to the first supporting portion 61.

The part formed of synthetic leather in the second portion 52 is stitched to the part formed of felt and the rigid members 84 in the first supporting portion 61 at a position shifted from the slit SL. That is, the second supporting portion 62 is connected with the first supporting portion 61 at the position shifted from the slit SL. In other words, the second supporting portion 62 is connected to the first supporting portion 61 with a part of the second supporting portion 62 overlapping with the first supporting portion 61. Thus, as shown in FIG. 7, a folding B between the first and second supporting portions 61 and 62 is shifted from the slit SL. In FIG. 7, the position at where the slit SL is provided is denoted by a symbol SL schematically.

As shown in FIG. 4, a hook and loop fastener 86 (fixing portion, attachment portion) is provided at a part of the first surface 81 of the second supporting portion 62. The hook and loop fastener 86 is, for example, a cloth with a plurality of annular projections to not scratch a thing to contact with. Here, the hook and loop fastener 86 may be a cloth with a plurality of hook-shaped projections.

The fixing portion 53 is formed in such a rectangular shape that looks like the first portion 51 divided in three, for example. The fixing portion 53 comprises an inner surface 88 (surface, portion, region) and an outer surface 89 (surface, portion, region). The inner surface 88 is formed of, for example, felt. The outer surface 89 is opposite to the inner surface 88 and is formed of, for example, synthetic leather.

Two hook and loop fasteners 91(fixing portion, attachment portion) are, for example, stitched on the inner surface 88. The hook and loop fasteners 91 correspond to the hook and loop fastener 73 of the first portion 51 and the hook and loop fastener 86 of the second portion 52.

The fixing portion 53 is connected with the second supporting portion 62 of the second portion 52 through a second connecting portion 56. Thus, the fixing portion 53 is positioned opposite to the first portion 51 interposing the second portion 52 therebetween.

The second connecting portion 56 is formed of, for example, synthetic leather and is flexible. Thus, the second connecting portion 56 is rotatable with respect to the second supporting portion 62 of the second portion 52. The width of the second connecting portion 56 is wider than the thickness of the receiver 11. The second connecting portion 56 may be formed of, for example, elastic rubber to set the width of the second connecting portion 56 narrower than the thickness of the receiver 11.

The holding portion 54 extends from the end of the second portion 52 together with the first connecting portion 55. The holding portion 54 is formed of, for example, felt and is flexible. A hook and loop fastener 93 is, for example, stitched to the end of the holding portion 54. The holding portion 54 is, as shown in FIG. 2, fixed in a rounded shape and configured to hold the cable 13 for containment.

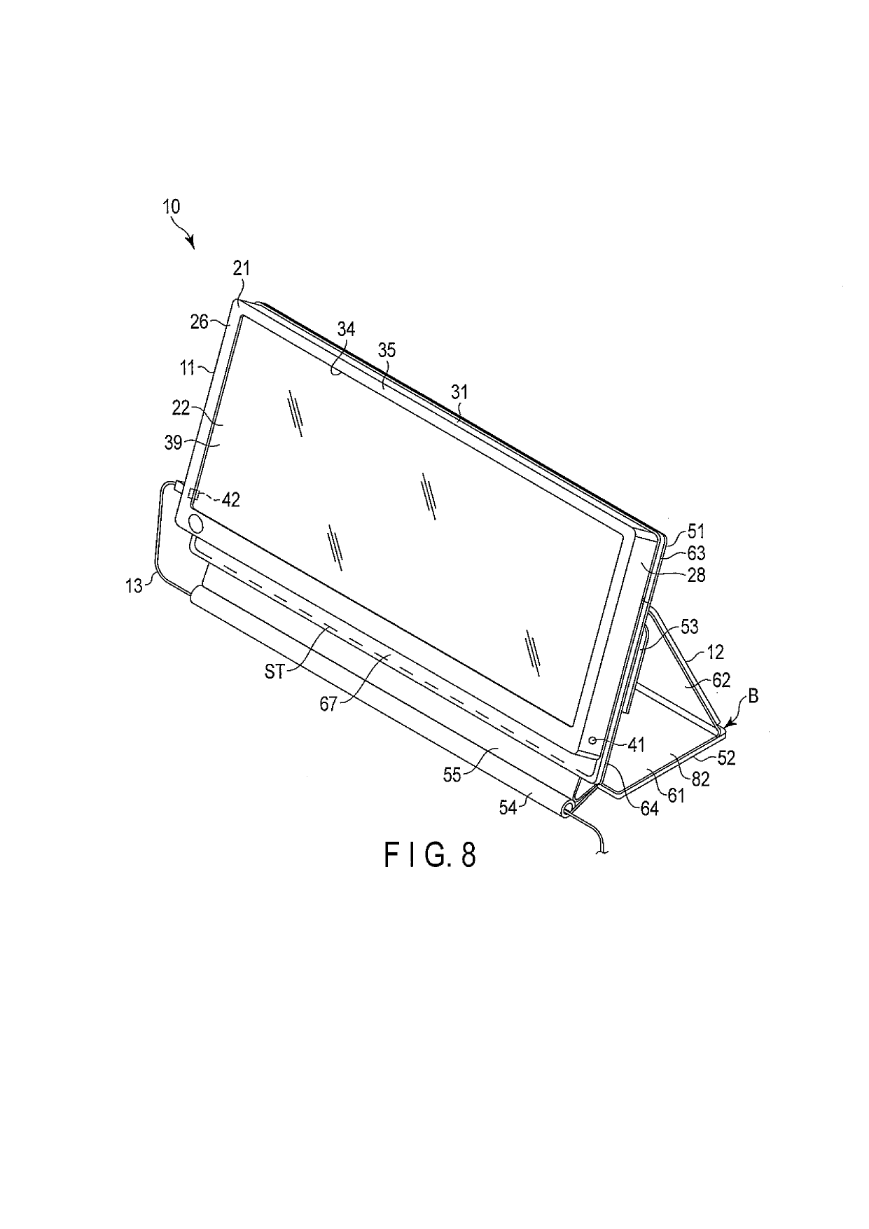

The TV 10 is transformable between first and second forms. In the first form of the TV 10, the cover 12 covers the receiver 11 for protection. In the second form of the TV 10, the cover 12 is used for a stand of the receiver 11. FIG. 8 is a perspective view of the TV 10 in the second form. On the other hand, FIG. 1 shows the TV in the first form.

As shown in FIG. 2, in the first form, the second portion 52 covers the first surface 26 of the receiver 11. The receiver 11 is interposed between the first and second portions 51 and 52. Here, side surfaces 28 and 29 of the receiver 11 are exposed. Furthermore, the holding portion 54 is interposed between the first and second portions 51 and 52. In the first form, the holding portion 54 is configured to retain the cable 13.

The second portion 52 covers at least the display portion 39 of the receiver 11. As shown in FIG. 3, the second portion 52 contacts the frame portion 35 of the receiver 11. Thus, there is a gap between the second portion 52 and display portion 39.

As shown in FIG. 1, the fixing portion 53 is detachably attached to the first portion 51 according to the hook and loop fasteners 91 of the fixing portion 53 attached to the hook and loop fastener 73 of the first portion 51. The cover 12 is thus not unfold unintentionally. The cover 12 comprising the fixing portion 53 surrounds the receiver 11 over one round.

The holding portion 54 is rounded around the cable 13 and fixed annularly by the hook and loop fastener 93 to hold the cable 13. As shown in FIG. 1 with a broken line, the cable 13 is folded in three. The length of the holding portion 54 is substantially the same as the length of the cable 13 folded in three. The cable 13 may be folded in other way.

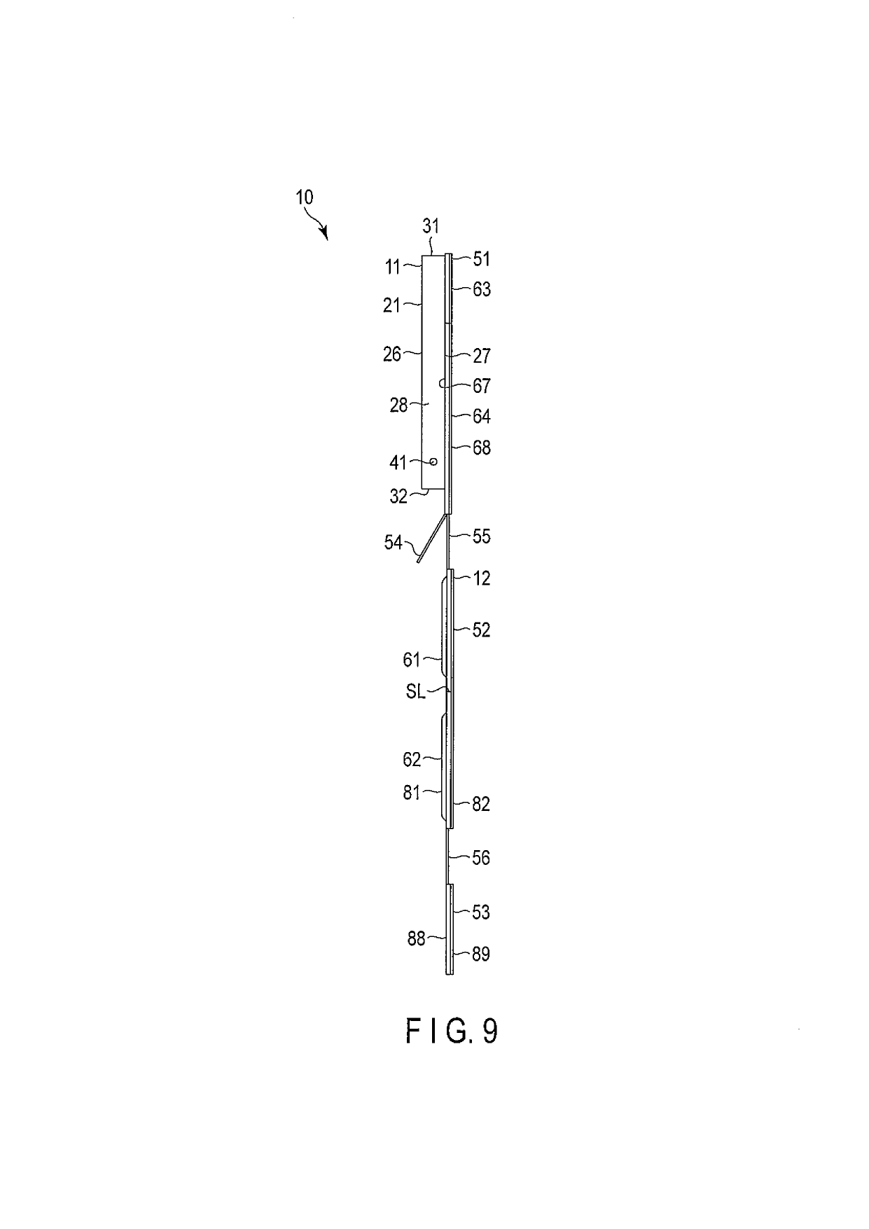

The TV 10 in the first form is transformable into the second form as described below. FIG. 9 is a side view showing the TV 10 with the cover 12 unfolded. Firstly, the fixing portion 53 is detached from the first portion 51. Next, the second portion 52 is rotated with respect to the first portion 51 and the fixing portion 53 is rotated with respect to the second portion 52. Thereby, the cover 12 is unfolded as shown in FIG. 9. When the cover 12 is unfolded, the first portion 51, second portion 52, fixing portion 53, first connecting portion 55 and second connecting portion 56 are arranged in a line.

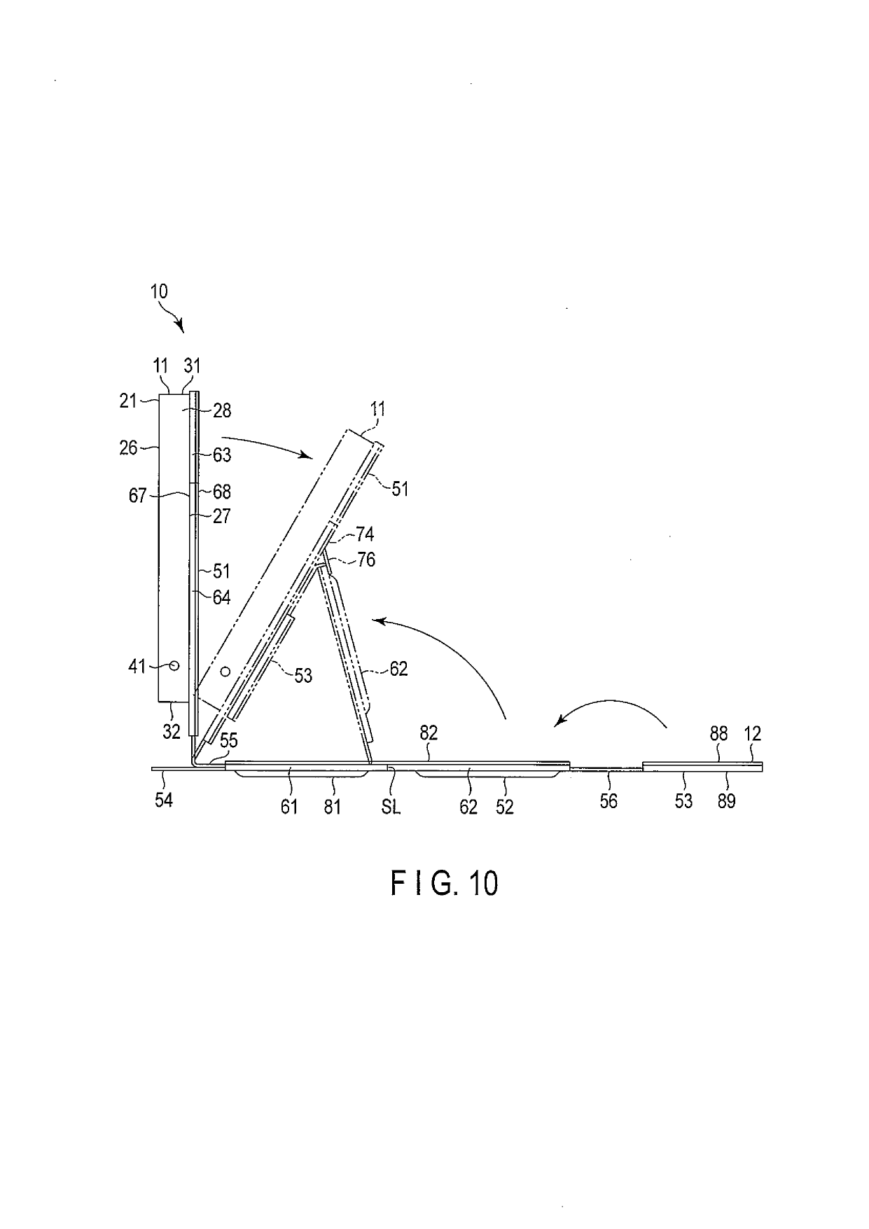

FIG. 10 is a side view of the TV 10 transforming into the second form. As shown by an arrow in FIG. 10, the second portion 52 is folded in two. That is, the second supporting portion 62 is rotated with respect to the first supporting portion 61. Then, the fixing portion 53 is rotated with respect to the second supporting portion 62. Thereby, as shown by a two-dotted chain line in FIG. 10, the first supporting portion 61, second supporting portion 62 and fixing portion 53 are arranged in substantially a triangular shape.

Next, as shown by an arrow in FIG. 10, the first portion 51 with the receiver 11 is rotated with respect to the second portion 52. Thereby, the outer surface 68 of the first portion 51 leans on the second supporting portion 62. That is, the second supporting portion 62 supports the outer surface 68 of the first portion 51. The second supporting portion 62 supports the receiver 11 in an inclined fashion as shown by a double-dot chain line in FIG. 10.

Next, as shown in FIG. 6, one of the tabs 76 of the adjustor 74 is peeled off from the outer surface 68 of the first portion 51. The hook and loop fastener 77 of the peeled-off tab 76 is attached to the hook and loop fastener 86 of the second supporting portion 62. Thereby, as shown in FIG. 10, the second supporting portion 62 is detachably attached to the tab 76 of the adjustor 74.

When fixing the second supporting portion 62 to the adjuster 74, a relative position between the first portion 51 and second supporting portion 62 is selectively adjusted depending on which one of the tabs 76 is attached to the second supporting portion 62. Thereby, the tilt angle of the first portion 51 is adjusted.

Furthermore, one of the connectors of the cable 13 is inserted into the USB socket 42. At that time, the cable 13 may be passed upon the holding portion 54 spread. As shown in FIG. 8, by rolling the holding portion 54 in a tubular shape, the holding portion 54 may guide the cable 13. The holding portion 54 is fixed in a tubular shape by the hook and loop fastener 93.

As explained above, the TV 10 is transformable into the second form, and as shown in FIG. 7, the TV 10 in the second form comprises the first surface 81 of the first supporting portion 61 to be grounded onto a ground surface G so that the cover 12 can be used as a stand. When the TV 10 in the second form is transformed into the first form, the process mentioned above is performed in reverse.

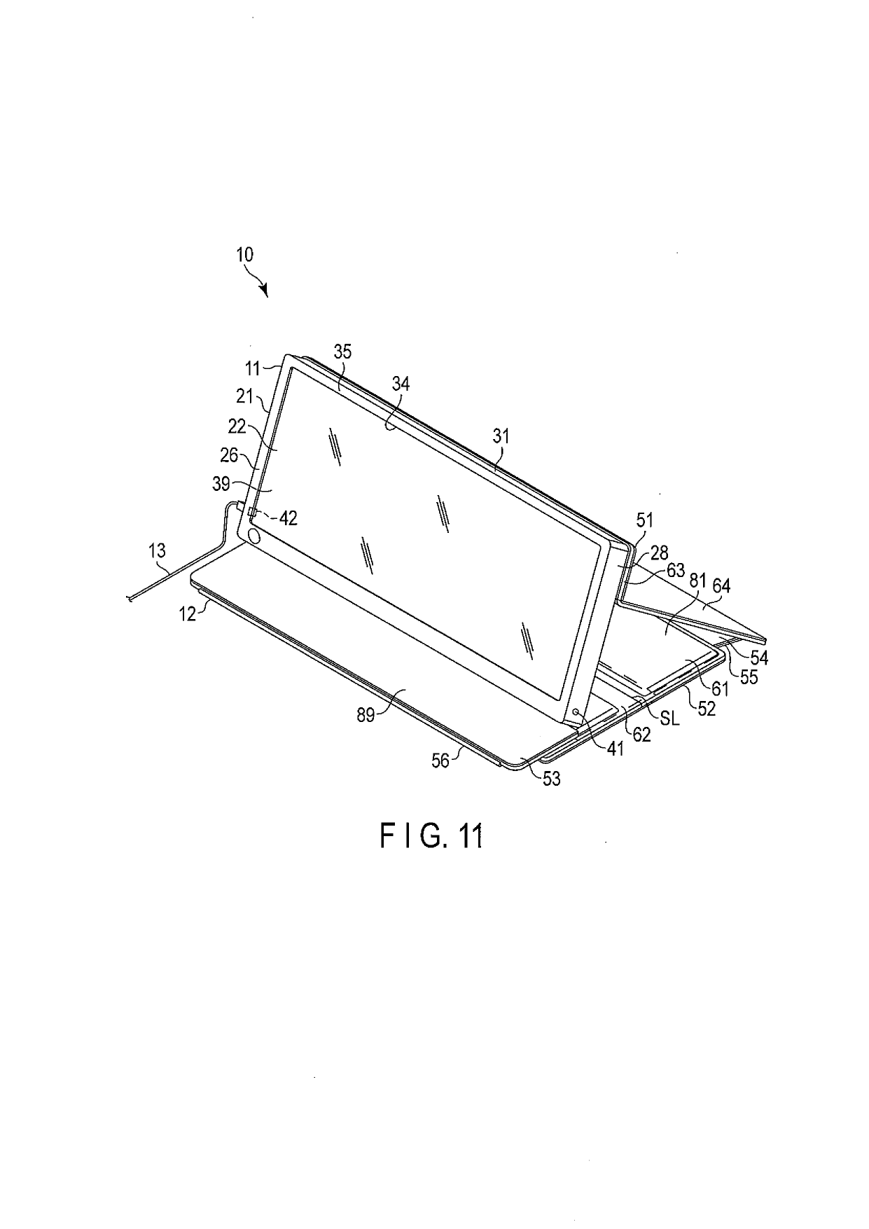

The TV 10 is transformable into the third form. In the third form, the cover 12 is used as a stand for the receiver 11 in a different way from the second form. FIG. 11 is a perspective view showing the TV 10 in the third form.

The TV 10 in the first form is transformable into the third form as described below. Firstly, the cover 12 is unfolded as shown in FIG. 9. Here, FIG. 9 shows that there is a gap of approximately 180° between the first and second portions 51 and 52; however, the degree of the gap is efficient when it is about 90°.

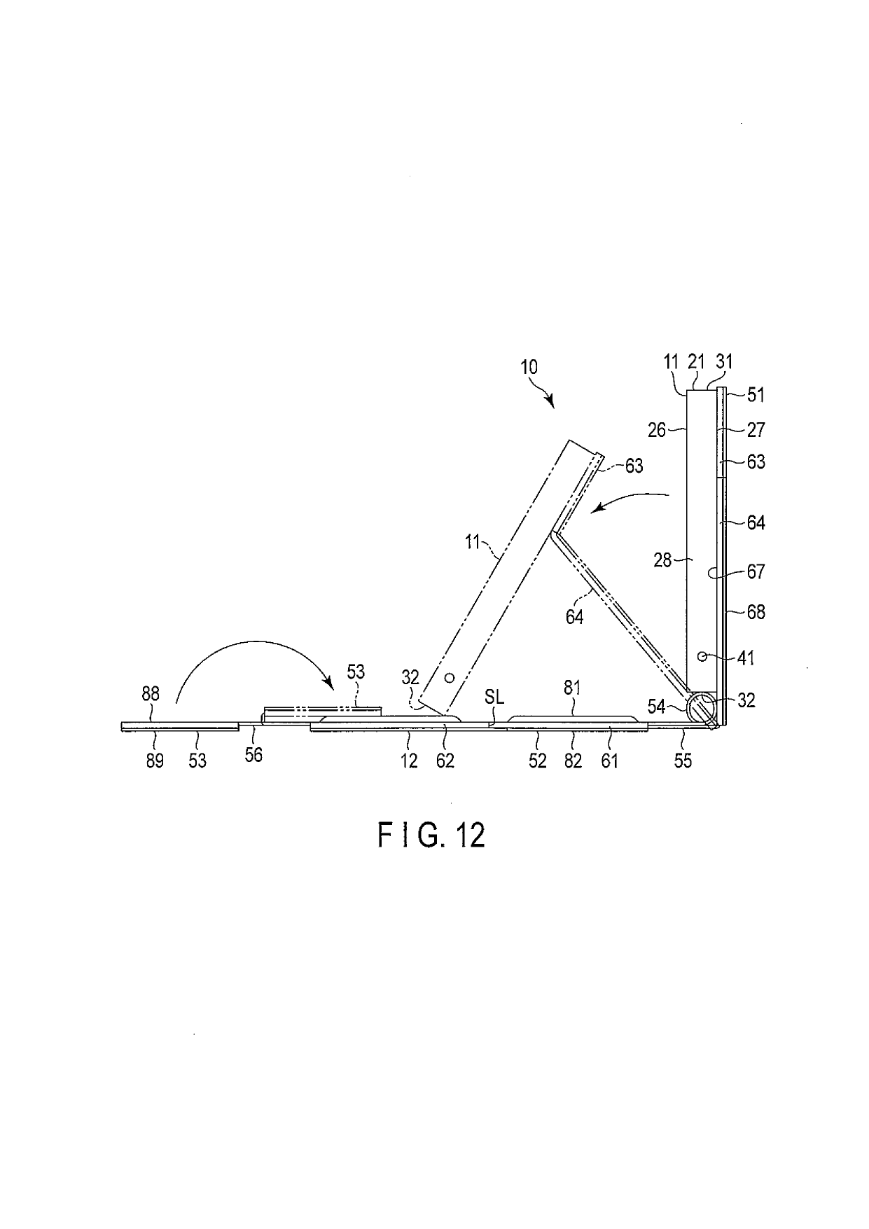

FIG. 12 is a side view showing the TV 10 transforming into the third form. As shown by an arrow in FIG. 12, the fixing portion 53 is rotated with respect to the second portion 52. The hook and loop fasteners 91 of the rotated fixing portion 53 are attached to the hook and loop fastener 86 of the second supporting portion 62 of the second portion 52, and thus, the fixing portion 53 is fixed to the second portion 52.

Next, as shown by an arrow in FIG. 12, the first portion 51 is folded in two. That is, the third supporting portion 63 is rotated with respect to the fourth supporting portion 64. Here, the hook and loop fasteners 37 and 72 fixing the receive 11 to the fourth portion 64 are peeled off. Furthermore, fourth supporting portion 64 is rotated with respect to the second portion 52. Thereby, as shown by a double-dotted chain line in FIG. 12, the receiver 11 is positioned on the first surface 81 of the second portion 52 leaning on the second portion 52.

The rotated fourth supporting portion 64 folds at the third supporting portion 63 in such a manner to cross the third supporting portion 63. Since the receiver 11 is fixed at the third supporting portion 63, the fourth supporting portion 64 connecting with the third supporting portion 63 supports the receiver 11 in an inclined fashion. In other words, the second supporting portion 62 supports the receiver 11 by extending a direction crossing the first portion 51.

Based on a position of the second portion 52 where the receiver 11 is disposed, the tilt angle of the receiver 11 is adjusted. When the tilt angle is large, the fixing portion 53 fixed to the second portion 52 contacts the end surface 32 of the receiver 11 to hold the receiver 11. The receiver 11 may be placed on the second portion 52 to directly cross the second portion 52 itself.

As explained above, the TV 10 is transformed into the third form. The TV 10 in the third form comprises the second surface 82 of the second portion 52 to be grounded so that the cover can be used as a stand. When the TV 10 in the third form is transformed into the first embodiment, the process mentioned above is performed in reverse. Furthermore, the TV 10 is transformable between the second and third forms.

The TV 10 comprising the above-mentioned structures is, by the rotation of the first and second supporting portions 61 and 62, transformable between the first form wherein the second portion 52 covers the first surface 26 of the receiver 11 and the second form wherein the second supporting portion 62 supports the first portion 51 to hold the receiver 11 in an inclined fashion. Thus, the cover 12 configured to cover the receiver 11 is usable as a stand without any difficulty.

The second supporting portion 62 of the second portion 52 is connected with the first supporting portion 61 rotatably with respect to the first supporting portion 61 at a position shifted from the slit SL. Thus, the folding B between the first and second supporting portions 61 and 62 is shifted from the slit SL. Thereby, the second portion 52 is foldable in two but still maintains rigidness thereof. In the first form, since the second portion 52 covers the first surface 26 of the receiver 11, the display portion 39 of the receiver 11 is protected by the second portion 52.

In the first form, the second portion 52 contacts the frame portion 35, there is a gap between the second portion 52 and the display portion 39. Thus, the second portion 52 is prevented from contacting the display portion 39 and the display 39 is protected.

The second portion 52 comprises, for example, the rigid member 84 and is more rigid than the first portion 51. Thereby, the second portion 52 is prevented from deforming by an external force and the display portion 39 is protected. Here, the second portion 52 may be formed of a material which is more rigid than the first portion 51.

The receiver 11 is detachably attached to the first portion 51 by the hook and loop fastener 36. The receiver 11 is thus easily attachable to the cover 12. The receiver 11 is easily detachable from the cover 12 and used. The receiver 11 is attachable to the fourth supporting portion 64 of the first portion 51 by the hook and loop fastener 37. Thereby, the fourth supporting portion 64 with the receiver 11 is prevented from rotating unintentionally. Furthermore, since each of the hook and loop fasteners 37 is smaller than the hook and loop fastener 36, the hook and loop fasteners 37 are easily peeled off. Thus, the TV 10 is easily transformable into the third form.

The fixing portion 53 connected with the second supporting portion 62 is, in the first form, detachably attached to the first portion 51. Thereby, an unintentional unfold of the cover 12 is prevented. In the third form, the fixing portion 53 contacts the end surface 32 of the receiver 11 and holds the receiver 11 there. Thereby, falling down of the receiver 11 is prevented.

The first surface 81 of the second portion 52 is formed of felt, which is not slippery in comparison with synthetic leather forming the second surface 82. Thus, in the second form, the TV 10 is prevented from slipping on the ground surface G such as a desk and the like. In the third form, the receiver 11 is prevented from slipping on the second portion 52, and thus, the tilt angle of the receiver 11 is easily adjusted.

In the second form, the second supporting portion 62 is selectively fixed to one of the tabs 76 of the adjustor 74. That is, the adjustor 74 selectively adjusts a relative position between the first portion 51 and the second supporting portion 62. Thereby, the tilt angle of the receiver 11 is easily adjusted. Furthermore, the hook and loop fastener 77 of the tabs 76 is attached to the hook and loop fastener 86 of the second supporting portion 62, the first portion 51 is prevented from unintentionally dislocating from the second supporting portion 62.

The holding portion 54 in the first form is positioned between the first and second portions 51 and 52 and holds the cable 13. Thereby, the delivery of the cable 13 is easy and there is no necessity to create a pocket or the like to project outside to contain the cable 13. Furthermore, in the second form, since the cable 13 is passed through the holding portion 54 fixed in a tubular shape, the cable 13 is contained in an orderly manner.

The TV 10 is, by rotating the third and fourth supporting portions 63 and 64, transformed into the third form which is different from the second form. Thereby, the cover 12 is used as a stand whose shape corresponds to a condition for use. For example, the TV 10 in the second form is placed on a desk, its occupation area on the desk is smaller than that of the TV 10 in the third form and the first surface 81 of the second portion 52 which is formed of not-slippery felt contacts the ground. On the other hand, in the third form, the tilt angle of the receiver 11 is easily adjusted and the second surface 82 of the second portion 52 which is formed of contamination-resistant synthetic leather contacts the ground.

The first and second portions 51 and 52 are formed in a rectangular shape larger than the receiver 11. In other words, the outer peripheral portions of the first and second portions 51 and 52 project from the side surfaces 28 and 29 and end surfaces 31 and 32 of the receiver 11. Therefore, even if the TV 10 in the first form falls to the ground, for example, in the side surface 28, the outer peripheral portions of the first and second portions 51 and 52 protect the receiver 11. Furthermore, the end portion 32 of the receiver 11 is distant from the end portion 51a of the first portion 51. Thus, in the second form, a position of the display portion 39 is higher than that of the second supporting portion 62 contacting the ground. Therefore, the display portion 39 is easily seen from a viewer.

The stitches ST are stitched at the periphery of the inner surface 67 of the first portion 51, and the stitches ST may be used as a target mark when the receiver 11 is attached to the first portion 51. Thus, the receiver 11 is accurately attached to the first portion 51 by using the stitches ST.

The end surfaces 28 and 29 of the receiver 11 are exposed. Therefore, various terminals are easily inserted into the power supply socket 41 and USB socket 42 provided in the side surfaces 28 and 29, respectively.

The power socket 41 and USB socket 42 are provided near to the one end surface 32 of the casing 21. Therefore, for example, when the cable 13 is connected with the USB socket 42 the cable 13 does not prevent the use of the TV 10 or harm a fine exterior of the TV 10.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, the cover 12 is usable for not only the TV 10 but also a display device of a personal computer, and any other electronic apparatus comprising a display portion such as a slate type computer and a smart phone.

The cover 12 is formed of, for example, synthetic leather only or felt only. Furthermore, the material forming the cover 12 is not limited to the above-mentioned synthetic leather and felt. For example, the cover 12 may be formed of synthetic resin, synthetic fiber, textiles, etc.

The attachment portion detachably attaching each element is not limited to a hook and loop fastener. Other materials such as, for example, screw, tuck, snap button and magnet are used to form the attachment portion.

The adjustor 74 comprises two tabs 76 but it is not limited to such a structure. The adjustor 74 may comprise three or more tabs 76, a long tab to adjust a relative position between the first portion 51 and the second supporting portion 62 in a non-step manner, and any other elements.

What is claimed is:

1. A television receiver comprising:
a receiver comprising a tuner, a first surface and a second surface in an opposite side of the first surface, the first surface comprising a display configured to display an image based on radio waves tuned by the tuner;
a first portion configured to be attached to the second surface of the receiver; and
a second portion comprising a first supporting portion rotatably connected with the first portion and a second supporting portion alongside the first supporting portion through a slit, the second supporting portion rotatably connected with the first supporting portion at a position shifted from the slit,
wherein the television receiver is configured to transform between a first form where the second portion covers the first surface and a second form where the second supporting portion supports the first portion to hold the receiver in a tilted state by rotating the first and second supporting portions.

2. The television receiver of claim 1, wherein
the first surface of the receiver comprises a frame portion surrounding the display, and
the second portion in the first form contacts the frame portion configured to provide a gap between the second portion and the display.

3. The television receiver of claim 1, wherein each of the first and second supporting portions of the second portion is more rigid than the first portion.

4. The television receiver of claim 2, wherein each of the first and second supporting portions of the second portion is more rigid than the first portion.

5. The television receiver of claim 1, wherein the receiver is attached to the first portion by an attachment portion in the second surface configured to detachably attach the second surface to the first portion.

6. The television receiver of claim 4, wherein the receiver is attached to the first portion by an attachment portion in the second surface configured to detachably attach the second surface to the first portion.

7. The television receiver of claim 1, further comprising a fixing portion rotatably connected with the second supporting portion at the opposite side of the first portion and detachably attached to the first portion in the first form.

8. The television receiver of claim 6, further comprising a fixing portion rotatably connected with the second supporting portion at the opposite side of the first portion and detachably attached to the first portion in the first form.

9. The television receiver of claim 1, wherein
the first supporting portion comprises a first supporting surface configured to face the receiver in the first form and a second supporting surface in an opposite side of the first supporting surface, and
the first supporting surface of the first supporting portion is rougher than the second supporting surface of the first supporting portion.

10. The television receiver of claim 8, wherein
the first supporting portion comprises a first supporting surface configured to face the receiver in the first form and a second supporting surface in an opposite side of the first supporting surface, and
the first supporting surface of the first supporting portion is rougher than the second supporting surface of the first supporting portion.

11. The television receiver of claim 1, wherein
the first portion comprises an inner surface attached to the receiver and an outer surface configured to be supported by the second supporting portion in the second form, and
the first portion in the second form comprises an adjustor configured to detachably attached to the second supporting portion to selectively adjust a relative position between the first portion and the second supporting portion.

12. The television receiver of claim 10, wherein
the first portion comprises an inner surface attached to the receiver and an outer surface configured to be supported by the second supporting portion in the second form, and
the first portion in the second form comprises an adjustor configured to detachably attached to the second supporting portion to selectively adjust a relative position between the first portion and the second supporting portion.

13. The television receiver of claim 1, further comprising a holding portion configured to position between the first and second portions in the first form and hold a cable connected to the receiver.

14. The television receiver of claim 12, further comprising a holding portion configured to position between the first and second portions in the first form and hold a cable connected to the receiver.

15. The television receiver of claim 1, wherein
the first portion comprises a third supporting portion attached to the receiver and a fourth supporting portion rotatably connected to the third supporting portion, and
the television receiver is further configured to transform into the first and second forms and further into a third form to hold the receiver in a tilted state while the receiver is placed on the second portion by rotating third and fourth supporting portions.

16. The television receiver of claim 14, wherein
the first portion comprises a third supporting portion configured to be attached to the receiver and a fourth supporting portion rotatably connected to the third supporting portion, and
the television receiver is further configured to transform into the first and second forms and further into a third form to hold the receiver in a tilted state while the receiver is placed on the second portion by rotating the third and fourth supporting portions.

17. A television receiver comprising:
a receiver comprising a first surface and a second surface in an opposite side of the first surface;
a first portion configured to support the receiver along the second surface of the receiver; and
a second portion comprising a connecting portion configured to contact a ground surface and a supporting portion configured to extend in a direction toward the first portion to support the receiver, the second portion configured to transform into a mode to cover the first surface, the supporting portion configured to partially overlap with and rotatably connected to the connecting portion to connect to the first portion.

18. An electronic apparatus comprising:
an apparatus comprising a first surface and a second surface in an opposite side of the first surface;
a first portion attached to the second surface of the apparatus; and
a second portion comprising a first supporting portion rotatably connected to the first portion and a second supporting portion arranged alongside the first supporting portion through a slit, the second supporting portion rotatably connected to the first supporting portion at a position shifted from the slit,
wherein the electronic apparatus is configured to transform between a first form where the second portion covers the first surface and a second form where the second supporting portion supports the first portion to hold the apparatus in a tilted state by rotating the first and second supporting portions.
